(19) United States
(12) Patent Application Publication
(10) Pub. No.: US 2013/0215357 A1
(43) Pub. Date: Aug. 22, 2013

(54) MODULIZED FRONT FRAME STRUCTURE AND LIQIUID CRYSTAL DISPLAY DEVICE USING THE SAME

(71) Applicant: Ze-Xin Wu, Shenzhen (CN)

(72) Inventor: Ze-Xin Wu, Shenzhen (CN)

(21) Appl. No.: 13/508,505

(22) PCT Filed: Mar. 13, 2012
(86) PCT No.: PCT/CN2012/072232

§ 371 Date: May 7, 2012

(30) Foreign Application Priority Data
Feb. 17, 2012 (CN) 201210036993.9

(51) Int. Cl. H05K 7/18; G02F 1/1333

(52) U.S. Cl. 349/58; 211/26

(57) ABSTRACT

A modulized front frame structure and a liquid crystal display device using the same are provided. The modulized front frame structure is a linear elongated metal sheet member comprising: a pressing part being pressed against on a top end of a lateral side of a liquid crystal panel, and a fixing part being bent extending from the pressing part and being pressed against on an outer surface of a rear cover, wherein the pressing part and the fixing part are integrally formed, the rear cover is used for disposing the liquid crystal panel, and the fixing part comprising at least an installation hole and the installation hole is used for fixing the fixing part on the rear cover by a fastener passing through, so as to reduce the manufacturing cost, the material cost, and the transportation cost.

### FIELD OF THE INVENTION

The present invention relates to a liquid crystal display (LCD) device, and more particularly to a modulized front frame structure of LCD device.

### BACKGROUND

A conventional LCD device usually includes a front frame, a bottom cover and a liquid crystal panel. The front frame and the bottom cover are incorporated with each other, and the liquid crystal panel is installed in a chamber enclosed by the front frame and the bottom cover. Referring to FIG. 1, the front frame 1a usually is a sheet metal structure, and includes a rectangle enclosed ring constituted by four side bars, wherein two corresponding side bars 11a have two installation holes 111a, respectively. By screws passing through the installation holes 111a, the front frame 1a and the bottom cover can be combined together in order to fix the liquid crystal panel. For the conventional front frame structure, if the front frame 1a is a one-piece structure, a large portion of the sheet metal in the middle of the structure can't be utilized, thereby causing the waste of material. However, if the front frame 1a is a two-piece combined structure, the manufacture cost will be increased due to an additional assembly process. Therefore, the conventional front frame have the problems of high manufacturing cost, high material cost and high transportation cost.

### SUMMARY

The objective of the present invention is to provide a modulized front frame structure capable of reducing the manufacturing cost, the material cost, and the transportation cost.

To achieve the above objectives, the present invention provides a modulized front frame structure, which is a linear elongated metal sheet member, comprising: a pressing part being pressed against on a top end of a lateral side of a liquid crystal panel; and a fixing part bent extending from the pressing part and being pushed against on an outer surface of a rear cover, wherein the pressing part and the fixing part are integrally formed, the rear cover is used for disposing the liquid crystal panel, and the fixing part comprises at least an installation hole, and the installation hole is used for fixing the fixing part on the rear cover by a fastener passing through.

In one embodiment of the present invention, the fixing part is bent extending from an outer edge of the pressing part, and pressed against on the outer surface of the rear cover; thereby the fixing part can be fixed on the rear cover from a lateral side by a fastener passing through the installation hole.

In one embodiment of the present invention, it further comprises a connecting part which is disposed between the pressing part and the fixing part. The connecting part is bent extending from an outer edge of the pressing part, and pressed against on the outer surface of the rear cover; the fixing part is formed by extending inward from a bottom edge of the connecting part, and pressed against on the bottom portion of the rear cover, thereby it can be fixed from the bottom surface to the rear cover by a fastener passing through the installation hole. The length of the fixing part which is a distance extending toward the center direction of the liquid crystal panel is larger than the length of the pressing part which is a distance extending toward the center direction of the liquid crystal panel.

Preferably, the number of the installation hole in the fixing part may be two.

To achieve the above-mentioned objectives, the present invention further provides a liquid crystal display (LCD) device, comprising: a liquid crystal panel, a rear cover for disposing the liquid crystal panel, and a plurality of modulized front frame structures cooperated with the rear cover for disposing the liquid crystal panel. Each modulized front frame structure is a linear elongated metal sheet member, comprising: a pressing part being pressed against on a top end of a lateral side of a liquid crystal panel; and a fixing part being bent extending from the pressing part and comprises at least an installation hole, and the installation hole is used for fixing the fixing part on the rear cover by a fastener passing through.

In one embodiment of the present invention, the fixing part of each modulized front frame structure is formed by vertically extending downward from an outer edge of the pressing part, and pressed against on the outer surface of the rear cover, thereby the fixing part can be fixed on the rear cover from a lateral side by a fastener passing through the installation hole.

In another embodiment of the present invention, each modulized front frame structure further comprises a connecting part which is formed between the pressing part and the fixing part. The connecting part is bent extending from an outer edge of the pressing part, and pressed against on the outer surface of the rear cover; the fixing part is extending inward from the connecting part, and being pressed against on the bottom portion of the rear cover, thereby it can be fixed to the rear cover from a bottom surface by a fastener passing through the installation hole. The length of the fixing part which is a distance extending toward the center direction of the liquid crystal panel is lager than the length of the pressing part which is a distance extending toward the center direction of the liquid crystal panel.

Preferably, the number of the installation hole in the fixing part of each modulized front frame structure may be two.

Compared with the conventional art, the modulized front frame structure of the present invention and an LCD device having the same can effectively cooperate with a rear cover to fix the liquid crystal panel by using a liner elongated sheet metal of which the pressing part and the fixing part are integrally formed, such that the manufacturing cost, the material cost, and the transportation cost can be reduced.

### BRIEF DESCRIPTION OF THE DRAWINGS

FIG. 1 is a perspective view of a conventional front frame structure of an LCD device.

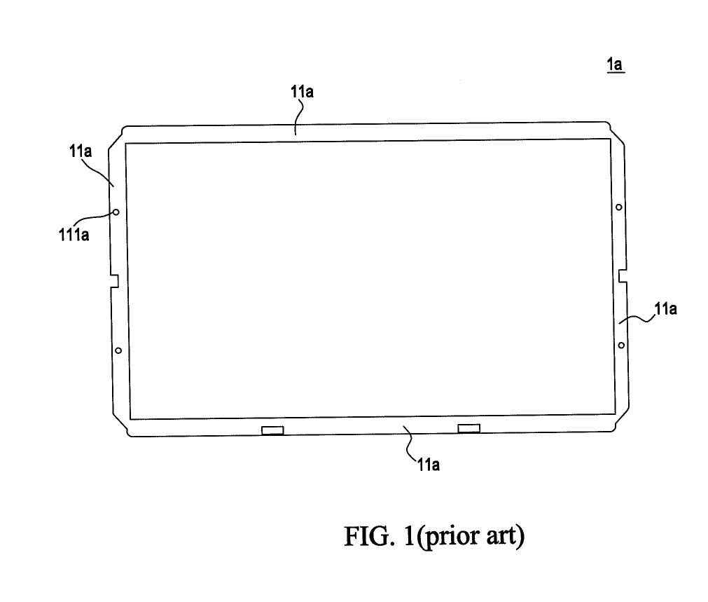

FIG. 2 is a perspective view of a modulized front frame structure according to a first embodiment of the present invention.

FIG. 3 is a perspective view of an LCD device according to the first embodiment of the present invention.

FIG. 4 is a perspective view of a modulized front frame structure according to a second embodiment of the present invention.

FIG. 5 is a perspective view of an LCD device according to the second embodiment of the present invention.

### DETAILED DESCRIPTION OF THE EMBODIMENTS

Hereinafter, preferred embodiments of the present invention will be described in detail with reference to the accompanying drawings.

The present invention provides a modulized front frame structure of an LCD device, which is a linear elongated metal sheet member, comprising: a pressing part being pressed against on a top end of a lateral side of a liquid crystal panel; and a fixing part being bent extending from the pressing part and being pressed against on an outer surface of a rear cover, wherein the pressing part and the fixing part are integrally formed, the rear cover is used for disposing the liquid crystal panel, and the fixing part comprises at least an installation hole and the installation hole is used for fixing the fixing part on the rear cover by a fastener passing through.

The present invention further provides a liquid crystal display (LCD) device, comprising: a liquid crystal panel, a rear cover for disposing the liquid crystal panel, and a plurality of modulized front frame structures cooperated with the rear cover for disposing the liquid crystal panel. Each modulized front frame structure is a linear elongated metal sheet member, comprising: a pressing part being pressed against on a top end of a lateral side of the liquid crystal panel; and a fixing part being bent extending from the pressing part and comprises at least an installation hole, and the fixing part can be fixed on the rear cover by a fastener passing through the installation hole.

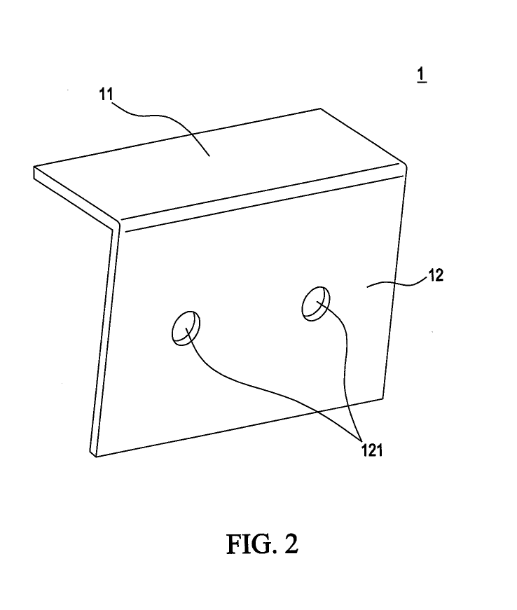

FIG. 2 is a perspective view of a modulized front frame structure according to a first embodiment of the present invention. The modulized front frame structure 1 is a linear elongated metal sheet member and has an L shape in the cross section. The modulized front frame structure 1 comprises a pressing part 11 being pressed against on a top end of a lateral side of a liquid crystal panel; and a fixing part 12 being formed by vertically extending downward from the pressing part 11 and pressed against on an outer surface of a rear cover, and having two installation holes 121 thereon, such that the fixing part 12 can be fixed on the rear cover from a lateral side by a fastener passing through the installation holes 121. Preferably, the number of the installation hole 121 in the fixing part 12 may be two. In other embodiments, the number of the installation hole 121 may be one, or three, or more than three.

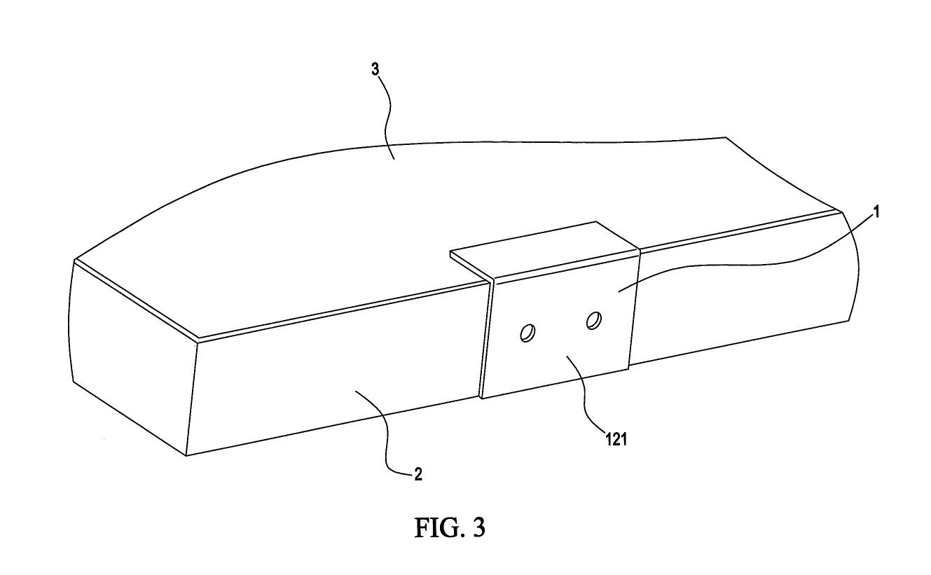

FIG. 3 is a perspective view of an LCD device according to the first embodiment of the present invention, which comprises a liquid crystal panel 3, a rear cover 2 for disposing the liquid crystal panel 3, and a plurality of the above-mentioned modulized front frame structure 1 for cooperating with the rear cover 2.

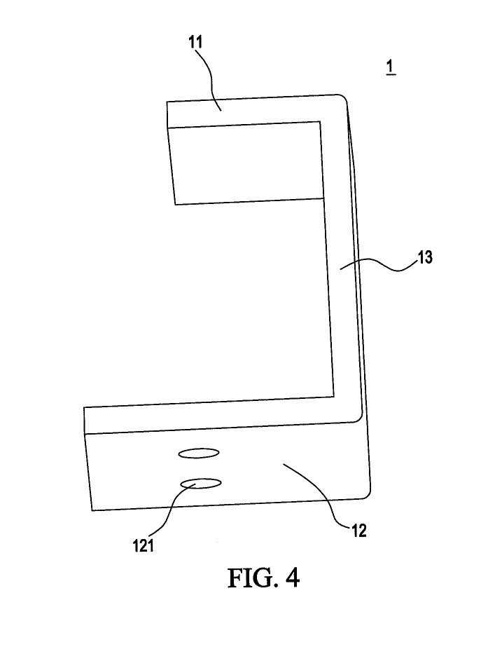

FIG. 4 is a perspective view of a modulized front frame structure according to a second embodiment of the present invention. The difference between the first embodiment and the second embodiment lies in that: the structure has a U shape in the cross section and further includes a connecting part 13.

The connecting part 13 is formed between the pressing part 11 and the fixing part 12, and the connecting part 13 is formed by vertically extending downward from an outer edge of the pressing part 11, and pressed against on the outer surface of the rear cover; the fixing part 12 is formed by extending inward horizontally from a bottom edge of the connecting part 13, and pressed against on the bottom portion of the rear cover, thereby the fixing part 12 can be fixed to the rear cover 2 from the bottom surface of the rear cover 2 by a fastener passing through the installation hole 121.

The length of the fixing part 12 which is a distance extending toward the center direction of the liquid crystal panel is lager than the length of the pressing part 11 which is a distance extending toward the center direction of the liquid crystal panel.

Preferably, the number of the installation hole 121 in the fixing part 12 may be two; in the other embodiment, the number of the installation hole 121 may be one, or three, or more than three.

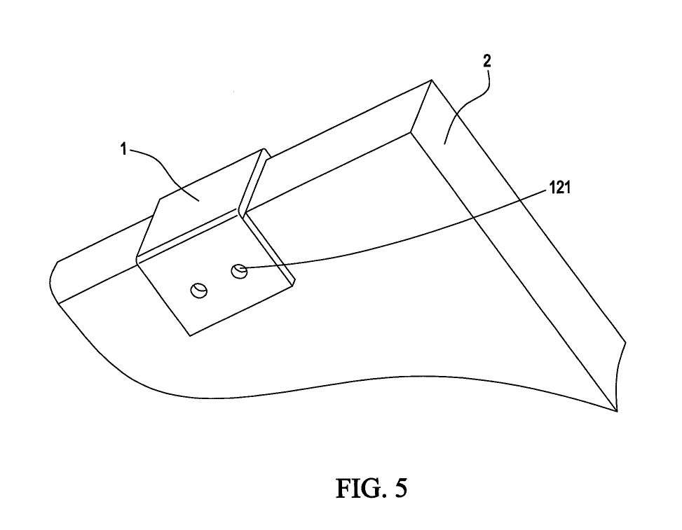

FIG. 5 is a perspective view of an LCD device according to the second embodiment of the present invention. The LCD device of the second embodiment comprises a rear cover 2 for disposing a liquid crystal panel, and a plurality of the above-mentioned modulized front frame structure 1 for cooperating with the rear cover 2.

In practice, the LCD device of the present invention may have the above mentioned modulized front frame structures 1 on two corresponding lateral sides; or may have the above mentioned modulized front frame structures 1 on each of four lateral sides. In addition, the number of the modulized front frame structure 1 in each lateral side may be one, two, three or more than three based on the size of the LCD device.

Compared with the conventional art, the effective benefits of the modulized front frame structure and an LCD device using the same of the present invention lie in that: the material cost, the manufacturing cost, and the transportation cost can be reduced by replacing an enclosed rectangle frame with the L-shaped member of the first embodiment and fixing the L-shaped member on the rear cover 2 from a lateral side of the L-shaped member by a screw, or by replacing an enclosed rectangle frame with the U-shaped member of the second embodiment and fixing the U-shaped member on the rear cover 2 from a bottom surface of the U-shaped member by a screw.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications, such as by replacing screws with bolts, latches or of fasteners, are possible in the component parts and/or arrangements of the subject combination arrangement within the scope of the disclosure, the drawings and the appended claims.

What is claimed is:

1. A modulized front frame structure, being a linear elongated metal sheet member comprising:
a pressing part being pressed against on a top end of a lateral side of a liquid crystal panel; and
a fixing part being bent and extending from the pressing part and being pressed against on an outer surface of a rear cover,
wherein the pressing part and the fixing part are integrally formed, the rear cover is used for disposing the liquid crystal panel, and the fixing part comprising at least an installation hole, and the installation hole is used for fixing the fixing part on the rear cover by a fastener passing through.

2. The modulized front frame structure as claimed in claim 1, wherein the fixing part is formed by vertically extending downward from an outer edge of the pressing part, and being pressed against on the outer surface of the rear cover, such that the fixing part is fixed on the rear cover from a lateral side by a fastener passing through the installation hole.

3. The modulized front frame structure as claimed in claim 1, further comprising:
a connecting part is disposed between the pressing part and the fixing part, and the connecting part is bent extending from an outer edge of the pressing part and pressed against on the outer surface of the rear cover; and
the fixing part is formed by extending inward from a bottom edge of the connecting part, and pressed against on the bottom portion of the rear cover, such that the fixing part is fixed to an outer surface of the rear cover from a bottom surface by a fastener passing through the installation hole.

4. The modulized front frame structure as claimed in claim 3, wherein a length of the fixing part which is a distance extending toward a center direction of the liquid crystal panel is lager than a length of the pressing part which is a distance extending toward the center direction of the liquid crystal panel.

5. The modulized front frame structure as claimed in claim 1, wherein a number of the installation hole in the fixing part is two.

6. A liquid crystal display device including a liquid crystal panel and a rear cover for disposing the liquid crystal panel, further comprising:
a plurality of modulized front frame structures cooperated with the rear cover for disposing the liquid crystal panel, and each modulized front frame structure is a linear elongated metal sheet member, comprising:
a pressing part being pressed against on a top end of a lateral side of the liquid crystal panel; and
a fixing part being bent extending from the pressing part and being pressed against on an outer surface of the rear cover, and the fixing part comprising at least an installation hole and the installation hole is used for fixing the fixing part on the rear cover from a lateral side by a fastener passing through.

7. The liquid crystal display device as claimed in claim 6, wherein the fixing part of each modulized front frame structure is formed by vertically extending downward from an outer edge of the pressing part, and pressed against on the outer surface of the rear cover, such that the fixing part is fixed on the rear cover from a lateral side by a fastener passing through the installation hole.

8. The liquid crystal display device as claimed in claim 6, wherein each modulized front frame structure further comprising:
a connecting part is formed between the pressing part and the fixing part, and the connecting part is bent extending from an outer edge of the pressing part and pressed against on the outer surface of the rear cover; and
the fixing part is formed by extending inward from a bottom edge of the connecting part, and pressed against on the bottom portion of the rear cover, such that the fixing part is fixed to the rear cover from a bottom surface by a fastener passing through the installation hole.

9. The liquid crystal display device as claimed in claim 8, wherein a length of the fixing part which is a distance extending toward a center direction of the liquid crystal panel is lager than a length of the pressing part which is a distance extending toward the center direction of the liquid crystal panel.

10. The liquid crystal display device as claimed in claim 6, wherein a number of the installation hole in the fixing part of each modulized front frame structure is two.
